(19) United States
(12) Patent Application Publication
(10) Pub. No.: US 2008/0128707 A1
(43) Pub. Date: Jun. 5, 2008

(54) SEMICONDUCTOR DEVICE AND METHOD FOR FABRICATING THE SAME

(75) Inventor: Kazuhiko Horino, Yamanashi (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: EUDYNA DEVICES INC., Yamanashi (JP)

(21) Appl. No.: 11/948,330

(22) Filed: Nov. 30, 2007

(30) Foreign Application Priority Data
Dec. 1, 2006 (JP) 2006-326123

(51) Int. Cl. H01L 29/205; H01L 21/205

(52) U.S. Cl. 257/76; 438/478; 257/E21.108; 257/E29.091

(57) ABSTRACT

A semiconductor device includes: an AlN layer provided on a substrate; a Si-doped GaN layer provided on the AlN layer; an undoped GaN layer provided on the Si-doped GaN layer; and an operation layer provided on the undoped GaN layer.

### BACKGROUND OF THE INVENTION

1. Field of the Invention

The present invention relates to semiconductor devices and methods for fabricating the same, and more particularly, to a semiconductor device having a semiconductor substrate in which a GaN (gallium nitride) layer is provided on an AlN (aluminum nitride) layer on a substrate, and a method for fabricating the same.

2. Description of the Related Art

A GaN layer may be grown directly on a substrate made of, for example, sapphire by MOCVD (Metal Organic Chemical Vapor Deposition). However, there is a difficulty in generation of microstructures of the GaN layer on the surface of the substrate. It is thus difficult to grow GaN crystal that has a little defect and dislocation. Thus, as described in Japanese Patent Application Publication No. 2001-196702, an AlN layer is grown on a substrate at a growth temperature as low as about 400° C., and a GaN layer is formed on the AlN layer. Thus, the surface of the AlN layer grown at the low temperature (low-temperature AlN layer) becomes microstructures, which make it possible to grow the GaN layer having good crystallinity.

However, the conventional art disclosed in the above application has the following disadvantage. The GaN layer on the AlN layer grown at the low temperature is grown at a temperature as high as 1000° C. or higher. This needs a process such that the grown temperature is raised for growth of the GaN layer after the AlN layer is grown. In order to avoid the above, the AlN layer may be grown at a temperature of 1000° C. or higher. However, this may increase edge dislocations in the GaN layer.

### SUMMARY OF THE INVENTION

The present invention has been made in view of the above circumstances, and aims at decreasing edge dislocations in the GaN layer.

According to an aspect of the present invention, there is provided a semiconductor device including: an AlN layer provided on a substrate; a Si-doped GaN layer provided on the AlN layer; an undoped GaN layer provided on the Si-doped GaN layer; and an operation layer provided on the undoped GaN layer.

According to another aspect of the present invention, there is provided a method for fabricating a semiconductor device including: forming an AlN layer on a substrate; forming a Si-doped GaN layer on the AlN layer; forming an undoped GaN layer on the Si-doped GaN layer; and forming an operation layer on the undoped GaN layer.

### BRIEF DESCRIPTION OF THE DRAWINGS

FIGS. 1A and 1B are cross-sectional views of a semiconductor substrate in accordance with a first embodiment;

FIG. 2 shows an x-ray diffraction rocking curve full width at half-maximums (XRC-FWHM) of the (1-102) plane of the semiconductor substrate as a function of the growth time of the Si-doped GaN layer;

FIGS. 3A through 3C show measurement results of the reflectance for different growth times of the Si-doped CaN layer; and

FIG. 4 is a cross-sectional view of an LED in accordance with a second embodiment.

### DESCRIPTION OF THE PREFERRED EMBODIMENTS

A description will now be given of embodiments of the present invention with reference to the accompanying drawings.

### First Embodiment

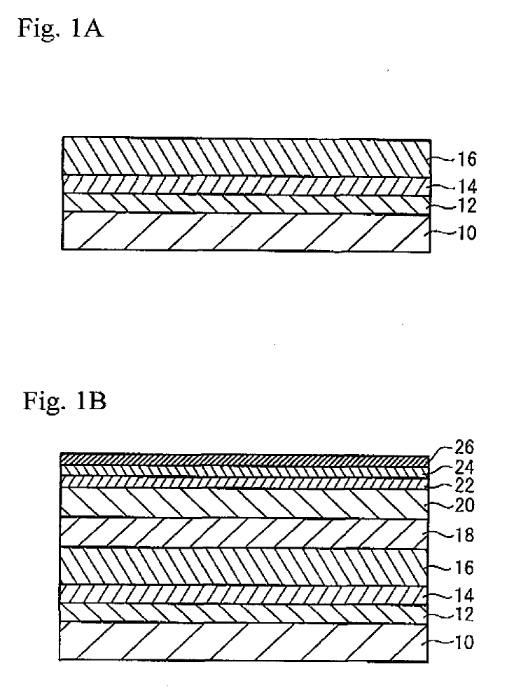

A first embodiment will be described with reference to FIGS. 1A and 1B. The first embodiment is an exemplary semiconductor substrate. Referring to FIG. 1A, there is illustrated a sapphire substrate 10 having a main surface of (0001) on which an AlN layer 12 having a thickness of 310 nm is formed by MOCYD. The conditions for growth are as follows. The growth temperature is changed between Growth 1 and Growth 2.

Gas flow rate: 70 μmoles/minute for TMA (trimethyl aluminum), 5580 μmoles for NH3 (ammonia), 20 SLM for H₂ (hydrogen)

Pressure: 50 Torr

Growth temperature: 1044° C. (Growth 1), 1142° C. (Growth 2)

Growth time: 300 seconds (Growth 1), 1500 seconds (Growth 2)

The GaN layer doped with a silicon at a dope concentration of 1.5×10¹⁹ cm⁻³ is grown on the AlN layer 12 under the following conditions.

Gas flow rate: 243 μmoles/minute for TMG, 2.2×10⁵ μmoles/minute for NH₃, 0.04 μmoles/minute for SiH₄ (silane), 20 SLM

Pressure: 200 Torr

Growth temperature: 1040° C.

Growth time; 150 seconds.

The above-mentioned growth conditions amount to an equivalent value of 77 nm obtained assuming that a flat film is grown. Then, an undoped GaN layer 16 having a thickness of 1330 nm is formed on a Si-doped GaN layer 14. The conditions for growth are as follows.

Gas flow rate: 243 μmoles/minute for TMG, 2.2×10⁵ μmoles/minute for NH₃, 20 SLM for H₂

Pressure: 200 Torr

Growth temperature: 1040° C.

Growth time: 2590 seconds.

As shown in FIG. 1B, grown are an n-type GaN layer 18 having a film thickness of 1380 nm, an N-type InGaN layer 20, an N-type GaN layer 22, a MQW (Multi Quantum Well) forming an active layer 24, and a p-type GaN layer 26 by MOCVD. The semiconductor substrate of the first embodiment is completed through the above-mentioned process.

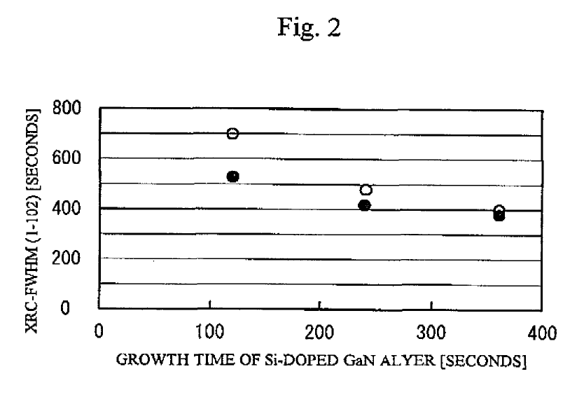

FIG. 2 shows an x-ray diffraction rocking curve full width at half-maximums (XRC-FWHH) of the (1-102) plane of the semiconductor substrate as a function of the growth time of the Si-doped GaN layer 14. Two dots for an identical growth time result from different samples. FIG. 2 shows that the XRC-FWHM becomes smaller as the growth time of the Si-doped GaN layer 14 becomes longer. It is known that the XRC-FWHM of the (1-102) plane correlates with the density of edge dislocations. It is thus possible to reduce the edge dislocations in the undoped GaN layer 16 by growing the Si-doped GaN layer 14 and then growing the undoped CaN layer 16.

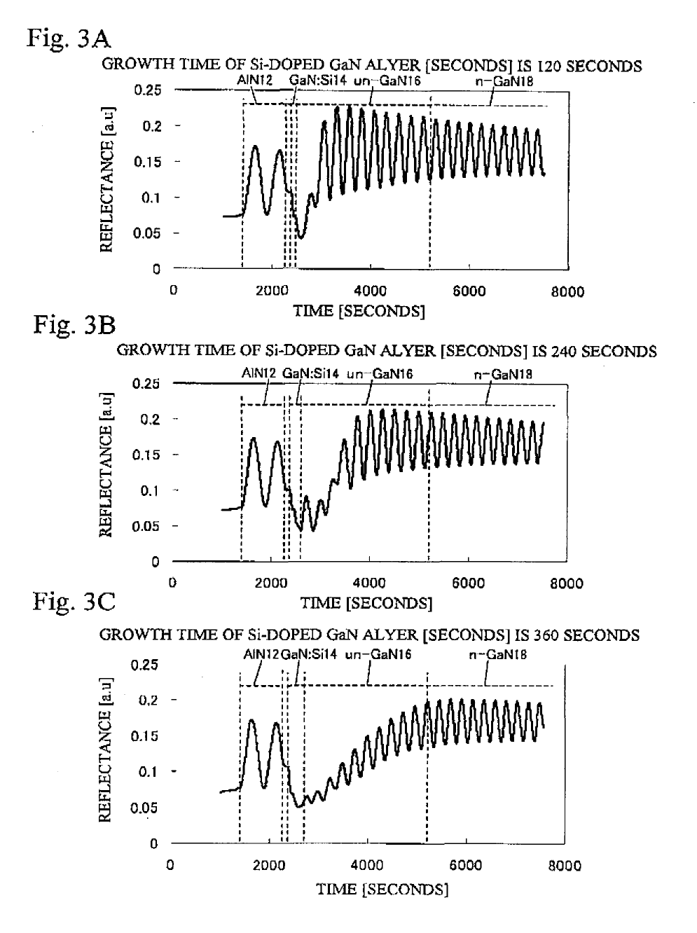

The inventor measured the reflectance by a reflectance measurement apparatus using laser light during growth of the AlN layer 12, the Si-doped GaN layer 14, the undoped GaN layer 16 and the n-type GaN layer IS in order to investigate the surface condition of the substrate during the epitaxial growth, FIGS. 3A through 3C show measurement results of the reflectance for different growth times of the Si-doped GaN layer 14. The ranges named AlN12, GaN:Si14, un-GaN16, n-GaN18 are the growth times during which the AlN layer 12, the Si-doped GaN layer 14, the undoped GaN layer 16 and the n-type GaN layer 18 are respectively grown. The growth temperature is changed at an interval between AlN12 and GaN:Si14.

As shown in FIGS. 5A through 3C, the reflectance of light is high when the AlN layer 12 is being grown. In contrast, the reflectance is low when the Si-doped GaN layer 14 is being grown. When the undoped GaN layer 16 is grown, the reflectance of light is gradually restored. The time it takes for the reflectance to be restored is short when the time for growth of the Si-doped GaN layer 14 is short as shown in FIG. 3A, and is long when the time for growth of the Si-doped GaN layer 14 is long as shown in FIG. 3C.

The mechanism for reducing the edge dislocations may be considered as follows from the results shown in FIGS. 3A through 3C. There are many edge dislocations in the AlN layer that is grown at a high temperature. In this case, when the GaN layer is grown on the AlN layer, edge dislocations may take place in the GaN layer. This may result from the following. In the initial stage of growth of GaN on the surface of the AlN layer grown at a high temperature, the three-dimensional microstructures generated on the AlN layer are crystal-grown and are combined with adjacent three-dimensional microstructures. At that time, the crystal surfaces of the three-dimensional microstructures on the AlN layer in which a large number of edge dislocations exist are finely different from each other, so that the crystal lattice is misaligned at the interfaces at which the adjacent three-dimensional microstructures are combined. This misalignment of the crystal lattice may cause edge dislocations. Thus, when the initial stage of growth of the GaN layer on the AlN layer has a high density of microstructures, there is a number of interfaces at which the three-dimensional microstructures are combined and there is a high density of edge dislocations.

When the GaN layer is grown in the (0001) direction, the GaN layer doped with Si at a high concentration is grown so that the three-dimensional microstructures expand at the growth rate in the lateral direction being approximately equal to that in the vertical direction. In contrast, the growth rate of the undoped GaN layer in the lateral direction is greater than that in the vertical direction. Thus, the undoped GaN layer expands so as to bury the spaces between the three-dimensional microstructures and is formed into a film during growth. According to the first embodiment, the Si-doped GaN layer 14 is grown on the AlN layer 12, and three-dimensional microstructures of GaN are thus grown so as to expand. At that time, the three-dimensional microstructures have respective unequal growth rates, so that large microstructures and small microstructures coexist. Thus, the surface has a large roughness, and the reflectance of light is decreased when the Si-doped GaN layer 14 is grown, as shown in FIGS. 3A through 3C. In growth of the Si-doped GaN layer 14, the three-dimensional microstructures are allowed to expand without any limitation. Thus, the large microstructures cover the small microstructures, so that the density of microstructures can be substantially reduced. Thus, the number of interfaces at which the three-dimensional microstructures are combined is reduced, so that the density of edge dislocations can be reduced. In contrast, when the undoped GaN layer is grown directly on the AlN layer 12, it is formed into a film shape during growth from the initial stage of growth, and the density of three-dimensional microstructure is not decreased unlike the Si-doped GaN layer 14. Thus, there are many interfaces at which the three-dimensional microstructures are combined so that the density of edge dislocations is higher than the first embodiment.

Then, the undoped GaN layer 16 is grown on the Si-doped GaN layer 14. The undoped GaN has a high rate of growth in the lateral direction. Thus, the spaces between the three-dimensional microstructures are buried with the undoped GaN layer 16, and a flat film is finally formed. According to FIGS. 3A through 3C, the reflectance of light can be gradually improved by growing the undoped GaN layer. This may result from gradual flattening of the surface.

FIGS. 3A through 3C show that the reflectance of light is restored more gradually as the time it takes to grow the Si-doped GaN layer is increased, in other words, as the thickness of the Si-doped GaN layer 14 is increased. Accordingly, the XRC-FWHM of (1-102) is decreased. That is, the edge dislocations is decreased. This suggests that the occurrence of edge dislocations is restrained by the Si-doped CaN layer 14. It is conceivable that the edge dislocations can be reduced by increasing the surface roughness by the Si-doped GaN layer 14 and decreasing the surface roughness by the undoped GaN layer 16.

As described above, the edge dislocations in the undoped GaN layer 16 can be reduced by providing, on the substrate TO, the AlN layer 12, the Si-doped GaN layer 14 and the undoped GaN layer 16.

Poor crystallinity of the high-temperature AlN layer 12 affects crystallinity of the undoped GaN layer 16. Thus, it is preferable that the high-temperature AlN layer 12 is grown at 1000° C. or higher, or at a temperature higher than the temperature at which the Si-doped GaN layer 14 is grown. In the high-temperature AlN layer 12 thus grown, the XRC-FWHM of the (0002) plane was 590-1110 seconds, and that of the (1-102) plane was 1120-2530 seconds. Preferably, the XRC-FWHM of the (1-102) plane of the high-temperature AlN layer 12 is equal to or less than 2500 seconds. It is thus possible to further improve the crystallinity of the undoped GaN layer 16. More preferably, the growth temperature of the AlN layer 12 is equal to or higher than 1050° C., and the XRC-FWHM is equal to or less than 2000 seconds.

When the AlN layer is grown at low temperatures, as described in the aforementioned application publication, the crystallinity of the AlN layer is very bad, and the XRC-FWHM is very large even when the layer as used in the first embodiment is grown on the AlN layer grown at low temperatures. The AlN layer 12 is not limited to the AlN layer grown at 1000° C. or higher, and may be an AlN layer formed by another method as long as the AlN layer 12 has good crystallinity.

The crystallinity such as the edge dislocations may be evaluated by measuring the XRC-FWHM of a plane other than the (1-102) plane. However, the rocking curve of the (1-102) plane can be measured accurately and easily. It is thus preferable that the XRC-FWHM involved in the (1-102) plane is measured in order to evaluate the crystallinity of the density of edge dislocations of the high-temperature AlN layer 12.

Good crystallinity was not obtained when the high-temperature AlN layer 12 was approximately 0.15 μm. Preferably, the high-temperature AlN layer 12 is 0.15 μm thick or more, and is more preferably 0.31 μm thick or more.

Since the AlN layer grown at low temperatures as described in the aforementioned application publication has poor crystallinity, the XRC-FWHM is very large. The density of edge dislocations cannot be satisfactorily reduced even by growing the GaN layer on the low-temperature AlN layer. Further, the growth temperature of the AlN layer and that of the GaN grown on the AlN layer are quite different from each other. According to the first embodiment, the growth temperature of the AlN layer may be made approximately equal to that of the GaN layer. By forming the Si-doped GaN layer 14 on the high-temperature AlN layer 12 and forming the undoped GaN layer 16 on the Si-doped GaN layer 14, the edge dislocations can be reduced. The reflectance of light on the surface at the step of growing the Si-doped GaN layer 14 is preferably less than the reflectance of light on the surface at the step of growing the high-temperature AlN layer 12, as shown in FIGS. 3A to 3C. Then, the undoped GaN layer 16 is grown so as to gradually restore the reflectance, so that the edge dislocations can be reduced.

The above-mentioned first embodiment forms, on the sapphire substrate in which the (0001) plane is the main surface, the AlN layer in the (0001) direction and the GaN layer. The present invention may use other substrates having a difficulty in growing the CaN layer directly thereon. Examples of these substrates are a sapphire substrate of the (11-20) plane, a spinel (MgAl₂O₄) substrate of the (111) plane, a MgO substrate of the (111) plane, a silicon substrate of the (111) plane, and a SiC substrate of the (0001) plane. Even for these substrates, the edge dislocations can be reduced by providing the high-temperature AlN layer 12, the Si-doped GaN layer 14 and the undoped GaN layer 16. The main surface of the substrate and the growth direction are preferably selected so that the growth rate of the Si-doped GaN layer 14 in the lateral direction is relatively low.

The growth time of the Si-doped GaN layer 14 has an optimal value that depends on the crystallinity of the AlN layer 12 and the growth conditions for the GaN layer. The thickness of the Si-doped GaN layer 14 is preferably equal to 30 nm to 200 nm, which are equivalent values in the flat film, and is more preferably equal to 50 nm to 100 nm. Preferably, the dope concentration of the Si-doped GaN layer 14 ranges from 5.0×10¹⁷ cM⁻³ to 1.0×10²⁰ cm⁻³.

### Second Embodiment

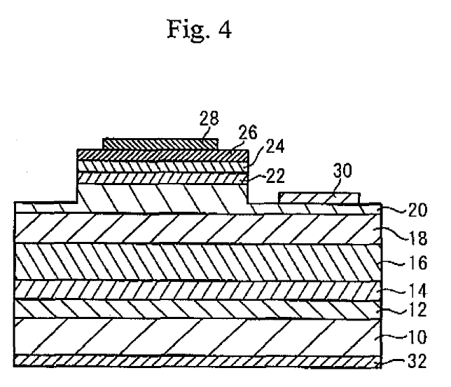

A second embodiment will now be described with reference to FIG. 4. The second embodiment is an exemplary LED (Light Emitting Diode) using the semiconductor substrate of the first embodiment. As shown in FIG. 4, a groove is formed by dry etching a partial region of a wafer of the semiconductor substrate of the first embodiment up to an n-type InGaN layer 20 of a nitride semiconductor layer. An n-type electrode 30 is formed on a part of the bottom surface of the groove by evaporation so as to be electrically connected to the n-type InGaN layer 20. A p-type electrode 28 is formed on a part of a p-type GaN layer 44 by evaporation so as to be electrically connected to the p-type GaN layer 44. The substrate 10 is grinded so as to have a thickness of up to 100 μm. A reflection film 32 made of gold (Au) is formed on the back surface of the substrate 10 by evaporation. The wafer is divided into chips of, for example, 300 μm×300 μm from the backside of the substrate 10 by scribing. The LED of the second embodiment is completed through the above-mentioned process. The semiconductor substrate of the first embodiment is characterized in that the undoped GaN layer 16 has good crystallinity and a reduced density of edge dislocations. Thus, the LED of the second embodiment is characterized in that the active layer 24 has good crystallinity and a reduced density of edge dislocations, and is therefore excellent in performance.

The above-mentioned second embodiment is an exemplary LED having an operation layer composed of the n-type GaN layer 18, the n-type InGaN layer 20, the n-type GaN layer 22, the active layer 24 and the p-type GaN layer 26. The present invention includes an FET in which the channel layer is an operation layer. Another layer may be interposed between the undoped GaN layer 16 and the operation layer.

The present invention is not limited to the specifically disclosed embodiments, but may include other embodiments and variations without departing from the scope of the present invention.

The present application is based on Japanese Patent Application No. 2006-326123 filed Dec. 1, 2006, the entire disclosure of which is hereby incorporated by reference.

What is claimed is:

1. A semiconductor device comprising:
an AlN layer provided on a substrate;
a Si-doped GaN layer provided on the AlN layer;
an undoped GaN layer provided on the Si-doped GaN layer; and
an operation layer provided on the undoped GaN layer.

2. The semiconductor device as claimed in claim 1, wherein an x-ray diffraction rocking curve full width at half-maximums of a (1-102) plane of the AlN layer is less than or equal to 2500 seconds.

3. The semiconductor device as claimed in claim 2, wherein the AlN layer, the Si-doped GaN layer and the undoped GaN layer are respectively grown by MOCVD.

4. A method for fabricating a semiconductor device comprising:
forming an AlN layer on a substrate;
forming a Si-doped GaN layer on the AlN layer;
forming an undoped GaN layer on the Si-doped GaN layer; and
forming an operation layer on the undoped GaN layer.

5. The method as claimed in claim 4, wherein the AlN layer is formed at a temperature higher than or equal to 1000° C.

6. The method as claimed in claim 4, wherein a reflectance of light of a surface during the Si-doped GaN layer is formed is less than that of a surface during the AlN layer is formed.

7. The method as claimed in claim 4, wherein a roughness of a surface of the Si-doped GaN layer is greater than a roughness of a surface of the AlN layer and the undoped GaN layer.

8. The method as claimed in claim 4, wherein the AlN layer, the Si-doped GaN layer and the undoped GaN layer are respectively layers grown by MOCVD.
